(19) United States
(12) Patent Application Publication
(10) Pub. No.: US 2015/0116974 A1
(43) Pub. Date: Apr. 30, 2015

(54) METHOD OF MANUFACTURING ELECTRONIC DEVICE, ELECTRONIC DEVICE, ELECTRONIC APPARATUS, MOVING OBJECT, AND LID BODY

(71) Applicant: Seiko Epson Corporation, Tokyo (JP)

(72) Inventors: Juichiro MATSUZAWA, Minowa (JP); Osamu KAWAUCHI, Shiojiri (JP); Shinya AOKI, Minowa (JP); Masaru MIKAMI, Kochi (JP)

(21) Appl. No.: 14/528,094

(22) Filed: Oct. 30, 2014

(30) Foreign Application Priority Data
Oct. 31, 2013 (JP) 2013-226522

(51) Int. Cl. H05K 5/06; H05K 5/02; B23K 1/00

(52) U.S. Cl. CPC H05K 5/066; B23K 1/0016; H05K 5/0239; B23K 2001/12
USPC 361/807; 228/101; 228/221; 312/223.1

(57) ABSTRACT

A method of manufacturing an electronic device in which a gyro element as an electronic component is accommodated in an internal space provided by a base and a lid as a lid body, includes: preparing the lid as the lid body in which a groove is provided in the surface which is a surface on the opposite side to the rear surface which is a surface on a side which is joined to the base; seam-welding the base and the lid at a site except for an unwelded site which includes a site corresponding to at least a portion of the groove, of a site planned to join the base and the lid; and welding the base and the lid at the unwelded site.

### BACKGROUND

1. Technical Field

The present invention relates to a method of manufacturing an electronic device, an electronic device, an electronic apparatus, a moving object, and a lid body.

2. Related Art

In recent years, the popularization of a portable electronic apparatus has progressed and the needs of a reduction in size and weight and a reduction in the cost of the electronic apparatus have increased accordingly. For this reason, in an electronic component which is used in the electronic apparatus, the needs of a reduction in size and a reduction in cost have increased while maintaining a high degree of accuracy. In particular, in a vibration device in which a vibration element is accommodated in a package, a vibration characteristic is maintained by maintaining an air-tight space in which the vibration element is accommodated, and therefore, various proposals have been made for a sealing technique thereof.

For example, in a joining method disclosed in JP-A-2000-223604, after a lid which covers an opening portion of a space in which a vibration device element (a vibration element) is accommodated, and a peripheral border of the opening portion are welded to each other while a portion (an unwelded portion) of a peripheral portion of the lid remains unwelded, deaeration is performed, and thereafter, the lid in the portion (the above-described unwelded portion) which is not welded and the peripheral border of the opening portion are sealed.

However, in the joining method shown in JP-A-2000-223604 described above, the lid and the peripheral border of the opening portion are welded to each other while a portion remains unwelded, and after the deaeration, the unwelded portion is welded, and therefore, it is difficult to stably control the dimensions or the like of the unwelded portion and it is not possible to perform stable deaeration and sealing, and thus there is a concern that a vibration characteristic may not be stable.

### SUMMARY

An advantage of some aspects of the invention is to solve at least a part of the problems described above, and the invention can be implemented as the following forms or application examples.

### APPLICATION EXAMPLE 1

This application example is directed to a method of manufacturing an electronic device in which an electronic component is accommodated in an internal space provided by a base and a lid body, including: preparing the lid body in which a groove is provided in a surface on the opposite side to a surface on a side which is joined to the base; seam-welding the base and the lid body at a site except for an unwelded site which includes a site corresponding to at least a portion of the groove, of a site planned to join the base and the lid body; and welding the base and the lid body at the unwelded site.

According to the method of manufacturing an electronic device, a portion in which a welding current does not flow at the time of seam welding in the first welding process is created by the groove provided in the surface on the opposite side to the surface on the side which is joined to the base in the lid body. In this way, a gap that is the unwelded site which includes a site corresponding to at least a portion of the groove can be provided between the lid body and the base. Since the gap is provided corresponding to the groove provided in the lid body, it is possible to stably form the gap without requiring dimensional control or the like. Therefore, a state is created where the internal space and the outside communicate with each other due to the gap, and thus it is possible to easily make the internal space have reduced pressure or an inert gas atmosphere. Then, by closing the gap of the communication portion by energy beam welding, it is possible to seal the internal space having reduced pressure or an inert gas atmosphere. In this way, sealing after gas generated during the joining of the lid body is removed from the inside of the package becomes possible, and thus it is possible to realize high-quality airtight sealing. In addition, for the seam welding of the base and the lid body in the first welding process, either a method of directly welding a base and a lid body or a method in which a separate joining body such as a metal body is provided between a base and a lid body and the base and the lid body are welded through the joining body can be applied.

### APPLICATION EXAMPLE 2

In the method of manufacturing an electronic device according to the application example described above, it is preferable that the groove reaches a position which overlaps the internal space, from an end portion of the outer periphery of the lid body in a plan view.

In this manner, the groove reaches a position which overlaps the internal space, from an end portion of the outer periphery of the lid body in a plan view, whereby the unwelded site can also be formed so as to reliably reach the internal space from the end portion of the outer periphery of the lid body. In this way, it becomes possible to reliably perform exhaust of the internal space.

### APPLICATION EXAMPLE 3

In the method of manufacturing an electronic device according to the application example described above, it is preferable that the method further includes: performing exhaust of the internal space through the groove between the seam-welding and the welding.

In this manner, a state is created where the internal space and the outside communicate with each other due to the groove provided in the lid body, and thus it is possible to easily make the internal space have reduced pressure or an inert gas atmosphere. Then, by performing exhaust of the internal space between the first welding process and the second welding process and closing the groove of the communication portion by welding, it is possible to seal the internal space having reduced pressure or an inert gas atmosphere. In this way, sealing after gas generated during the joining of the lid body is removed from the inside of the package becomes possible, and thus it is possible to realize high-quality airtight sealing through a simplified manufacturing process.

### APPLICATION EXAMPLE 4

In the method of manufacturing an electronic device according to the application example described above, it is preferable that a cross-sectional shape of the groove when viewed from an end portion side of the outer periphery is made such that an area of a bottom surface is smaller than an opening area.

By forming the cross-sectional shape of the groove in this manner, it becomes possible to easily perform pressing of a forming tool when forming the groove. In other words, in addition to good formability, it becomes possible to increase the strength of the tip of the forming tool, and thus it is possible to stably maintain the formability.

### APPLICATION EXAMPLE 5

This application example is directed to an electronic device manufactured using the method of manufacturing an electronic device according to the application example described above.

According to such an electronic device, it is possible to easily make the internal space have reduced pressure or an inert gas atmosphere and to perform reliable airtight sealing in the second welding process, and thus it becomes possible to obtain an electronic device with improved reliability of a characteristic.

### APPLICATION EXAMPLE 6

This application example is directed to an electronic apparatus including: the electronic device manufactured using the method of manufacturing an electronic device according to the application example described above.

According to such an electronic apparatus, it is possible to easily make the internal space have reduced pressure or an inert gas atmosphere and to perform reliable airtight sealing in the second welding process and since an electronic device with improved reliability of a characteristic is used, it is possible to make the electronic apparatus be an electronic apparatus with excellent reliability.

### APPLICATION EXAMPLE 7

This application example is directed to a moving object including: the electronic device manufactured using the method of manufacturing an electronic device according to the application example described above.

According to such a moving object, it is possible to easily make the internal space have reduced pressure or an inert gas atmosphere and to perform reliable airtight sealing in the second welding process and since an electronic device with improved reliability of a characteristic is used, it is possible to make the moving object be a moving object with excellent reliability.

### APPLICATION EXAMPLE 8

This application example is directed to a lid body which is welded to a base so as to form an internal space, including: a groove provided in a surface on the opposite side to a surface on a side which is joined to the base, wherein the lid body is seam-welded to the base at a site except for an unwelded site which includes a site corresponding to at least a portion of the groove, of a site planned to be welded to the base.

According to such a lid body, a portion in which a welding current does not flow when the lid body is seam-welded to the base is created by the groove provided in the surface on the opposite side to the surface on the side which is joined to the base in the lid body. In this way, a gap which is the unwelded site which includes a site corresponding to at least a portion of the groove can be provided between the lid body and the base. Since the gap is provided corresponding to the groove provided in the lid body, it is possible to stably form the gap without requiring dimensional control or the like. Then, a state is created where the internal space and the outside communicate with each other due to the gap, and thus it is possible to easily make the internal space have reduced pressure or an inert gas atmosphere.

### BRIEF DESCRIPTION OF THE DRAWINGS

The invention will be described with reference to the accompanying drawings, wherein like numbers reference like elements.

FIG. 1 is a perspective view showing an outline of a vibrator as a first embodiment of an electronic device.

FIGS. 2A and 2B are schematic diagrams showing the vibrator as the first embodiment of the electronic device, wherein FIG. 2A is a plan view and FIG. 2B is a cross-sectional front view.

FIG. 3 is a plan view showing a gyro element as an electronic component which is used in the electronic device.

FIGS. 4A, 4B, and 4C show an example of a lid body (a lid) which is used in the electronic device, wherein FIG. 4A is a plan view, FIG. 4B is a cross-sectional front view, and FIG. 4C is a cross-sectional view taken along line Q-Q of FIG. 4A.

FIGS. 5A to 5D are cross-sectional front views showing an outline of a process of manufacturing the vibrator as the electronic device.

FIG. 6 is a diagram showing a joint state of the lid and a base and is a cross-sectional view when a groove provided in the lid is viewed from the outer peripheral surface side of the lid.

FIGS. 7A, 7B, 7C, and 7D are diagrams showing a sealing process, wherein FIG. 7A is a plan view showing the state before sealing, FIG. 7B is a front view of FIG. 7A, FIG. 7C is a plan view showing the state after sealing, and FIG. 7D is a cross-sectional front view of FIG. 7C.

FIGS. 8A to 8E are front views showing modified examples of an opening shape of the groove.

FIG. 9 is a perspective view for describing another disposition example of the groove.

FIG. 10 is a cross-sectional front view showing an outline of a gyro sensor as a second embodiment of the electronic device.

FIG. 11 is a perspective view showing the configuration of a mobile type personal computer as an example of an electronic apparatus.

FIG. 12 is a perspective view showing the configuration of a mobile phone as an example of the electronic apparatus.

FIG. 13 is a perspective view showing the configuration of a digital still camera as an example of the electronic apparatus.

FIG. 14 is a perspective view showing the configuration of an automobile as an example of a moving object.

### DESCRIPTION OF EXEMPLARY EMBODIMENTS

### Electronic Device

Hereinafter, a method of manufacturing an electronic device according to the invention, and a lid body which is used therein will be described in detail with reference to the accompanying drawings.

### First Embodiment

First, a vibrator according to a first embodiment of an electronic device which is manufactured by applying the method of manufacturing an electronic device according to the invention will be described.

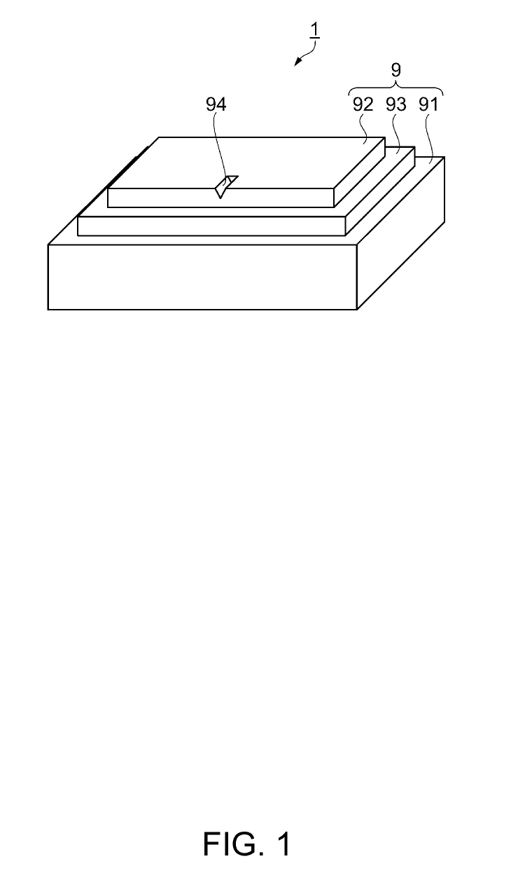

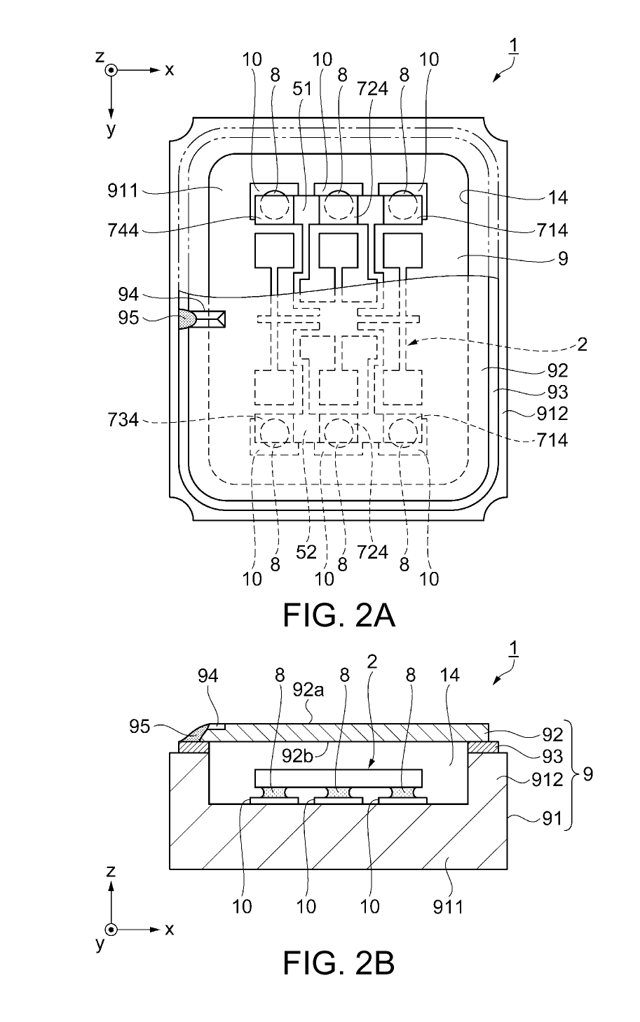

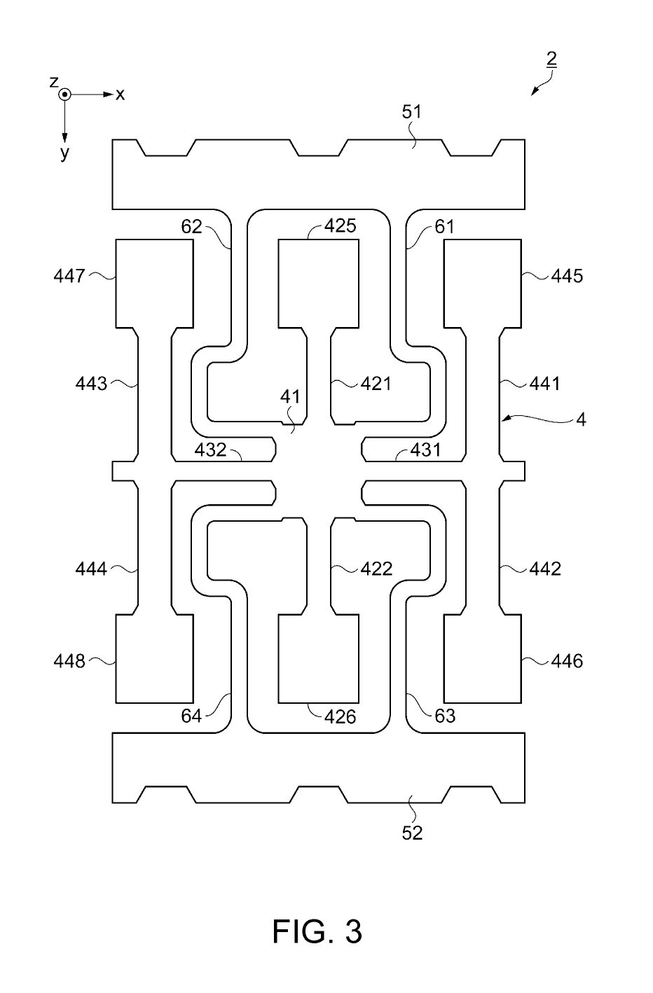

FIG. 1 is a schematic perspective view showing a vibrator as the first embodiment of the electronic device according to the invention. FIGS. 2A and 2B are diagrams showing an outline of the vibrator as the first embodiment of the electronic device according to the invention, wherein FIG. 2A is a plan view and FIG. 2B is a cross-sectional front view. FIG. 3 is a plan view showing a gyro element as an electronic component with which the vibrator shown in FIGS. 2A and 2B is provided. In addition, in the following, as shown in FIGS. 2A and 2B, three mutually-perpendicular axes will be respectively referred to as an x-axis, a y-axis, and a z-axis, and the z-axis coincides with a thickness direction of the vibrator. Further, a direction parallel to the x-axis will be referred to as an “x-axis direction”, a direction parallel to the y-axis will be referred to as a “y-axis direction”, and a direction parallel to the z-axis will be referred to as a “z-axis direction”.

A vibrator 1 as an example of the electronic device shown in FIGS. 1, 2A, and 2B has a gyro element (a vibration element) 2 as an electronic component, and a package 9 in which the gyro element 2 is accommodated in an internal space 14. Hereinafter, the gyro element 2 and the package 9 will be described in detail in order. In addition, the package 9 shown in FIG. 1 includes abase 91, a seam ring 93 as a joining material, and a lid 92 as the lid body. In the same drawing, a groove 94 provided in the lid 92 is shown. However, a state where sealing (a sealing process), which will be described later, is not performed is shown.

### Gyro Element

FIG. 3 is a plan view of the gyro element as viewed from the upper side (the lid 92 (described later) side and the z-axis direction in FIGS. 2A and 2B). In addition, in the gyro element, a detection signal electrode, detection signal wiring, a detection signal terminal, a detection ground electrode, detection ground wiring, a detection ground terminal, a drive signal electrode, drive signal wiring, a drive signal terminal, a drive ground electrode, drive ground wiring, a drive ground terminal, and the like are provided. However, these components are omitted in the same drawing.

The gyro element 2 is an “out-of-plane detection type” sensor which detects angular velocity around the z-axis, and although not shown in the drawing, the gyro element 2 is configured to include a base material, and a plurality of electrodes, wiring, and terminals provided on the surface of the base material. The gyro element 2 can be configured with a piezoelectric material such as a quartz crystal, lithium tantalate, or lithium niobate. However, among these, it is preferable that the gyro element 2 is configured with a quartz crystal. In this way, the gyro element 2 capable of exerting an excellent vibration characteristic (frequency characteristic) is obtained.

The gyro element 2 has a vibration body 4 which forms a so-called double T type, a first supporting portion 51 and a second supporting portion 52 as supporting portions which support the vibration body 4, and a first beam 61, a second beam 62, a third beam 63, and a fourth beam 64 as beams which connect the vibration body 4 and the first and second supporting portions 51 and 52.

The vibration body 4 has a width in an x-y plane and has a thickness in the z-axis direction. The vibration body 4 has a base 41 which is located at the center, a first detection vibrating arm 421 and a second detection vibrating arm 422 which extend from the base 41 to both sides along the y-axis direction, a first connection arm 431 and a second connection arm 432 which extend from the base 41 to both sides along the x-axis direction, a first drive vibrating arm 441 and a second drive vibrating arm 442 as vibrating arms extending from a tip portion of the first connection arm 431 to both sides along the y-axis direction, and a third drive vibrating arm 443 and a fourth drive vibrating arm 444 as vibrating arms extending from a tip portion of the second connection arm 432 to both sides along the y-axis direction. Weight portions (hammerheads) 425, 426, 445, 446, 447, and 448 as substantially rectangular wide portions each having a larger width than the base end side are respectively provided at tip portions of the first and second detection vibrating arms 421 and 422 and the first, second, third, and fourth drive vibrating arms 441, 442, 443, and 444. The weight portions 425, 426, 445, 446, 447, and 448 are provided, whereby the sensitivity for detection of the angular velocity of the gyro element 2 is improved.

Further, each of the first and second supporting portions 51 and 52 extends along the x-axis direction, and the vibration body 4 is located between the first and second supporting portions 51 and 52. In other words, the first and second supporting portions 51 and 52 are disposed so as to face each other along the y-axis direction with the vibration body 4 interposed therebetween. The first supporting portion 51 is connected to the base 41 through the first beam 61 and the second beam 62, and the second supporting portion 52 is connected to the base 41 through the third beam 63 and the fourth beam 64.

The first beam 61 connects the first supporting portion 51 and the base 41 through a gap between the first detection vibrating arm 421 and the first drive vibrating arm 441, the second beam 62 connects the first supporting portion 51 and the base 41 through a gap between the first detection vibrating arm 421 and the third drive vibrating arm 443, the third beam 63 connects the second supporting portion 52 and the base 41 through a gap between the second detection vibrating arm 422 and the second drive vibrating arm 442, and the fourth beam 64 connects the second supporting portion 52 and the base 41 through a gap between the second detection vibrating arm 422 and the fourth drive vibrating arm 444.

Each of the beams 61, 62, 63, and 64 is formed in an elongated shape having a meandering portion which extends along the y-axis direction while reciprocating along the x-axis direction and therefore, has elasticity in all directions. For this reason, even if an impact is applied from the outside, an action to absorb the impact at each of the beams 61, 62, 63, and 64 is provided, and therefore, it is possible to reduce or suppress detection noise due to this.

The gyro element 2 having such a configuration detects angular velocity ω around the z-axis in the following manner. In the gyro element 2, if an electric field is generated between a drive signal electrode (not shown) and a drive ground electrode (not shown) in a state where the angular velocity ω is not applied, each of the drive vibrating arms 441, 442, 443, and 444 performs flexural vibration in the x-axis direction. At this time, the first and second drive vibrating arms 441 and 442 and the third and fourth drive vibrating arms 443 and 444 perform vibration which is plane-symmetrical with respect to a y-z plane passing through the center point (the center of gravity), and therefore, the base 41, the first and second connection arms 431 and 432, and the first and second detection vibrating arms 421 and 422 almost do not vibrate at all.

If the angular velocity ω around the z-axis is applied to the gyro element 2 in a state where the drive vibration is performed, a Coriolis force in the y-axis direction acts on each of the drive vibrating arms 441, 442, 443, and 444 and the connection arms 431 and 432, and detection vibration in the x-axis direction is excited in response to the vibration in the y-axis direction. Then, a detection signal electrode (not shown) and a detection ground electrode (not shown) detect the distortions of the detection vibrating arms 421 and 422 generated due to the vibration, and thus the angular velocity ω is determined.

### Package

The package 9 is for accommodating the gyro element 2. In addition, in the package 9, as in the electronic device which will be described later, in addition to the gyro element 2, an IC chip or the like which performs the drive or the like of the gyro element 2 may be accommodated. The package 9 has a substantially rectangular shape in a plan view (an x-y plane view).

As shown in FIGS. 1, 2A, and 2B, the package 9 has the base 91 having a concave portion which is open at the upper surface, and the lid 92 as the lid body which is joined to the base through the seam ring 93 as the joining material so as to close the opening of the concave portion. Further, the base 91 has a plate-shaped bottom plate 911, and a frame-shaped side wall 912 provided at a peripheral portion of the upper surface of the bottom plate 911. The frame-shaped side wall 912 is provided with a substantially rectangular circumference, and in other words, the shape of the opening which is open at the upper surface of the concave portion is substantially rectangular. A concave portion surrounded by the plate-shaped bottom plate 911 and the frame-shaped side wall 912 becomes the internal space (the accommodation space) 14 in which the gyro element 2 as the electronic component is accommodated. The seam ring 93 formed of an alloy such as Kovar, for example, is provided on an upper surface 912a of the frame-shaped side wall 912. The seam ring 93 has a function as the joining material between the lid 92 and the side wall 912 and is provided in a frame shape (a substantially rectangular circumference) along the upper surface 912a of the side wall 912.

The lid 92 has a substantially rectangular outer shape, and the bottomed groove 94 is provided toward a central portion from an outer periphery in a surface 92a that is a surface on the opposite side to a side of the seam ring 93 provided on the upper surface of the side wall 912. In addition, the details regarding the configuration of the lid 92 will be described later. The groove 94 is disposed so as to overlap the internal space 14 in a plan view from an end on the outer periphery side of the lid 92 when the lid 92 is placed on the seam ring 93.

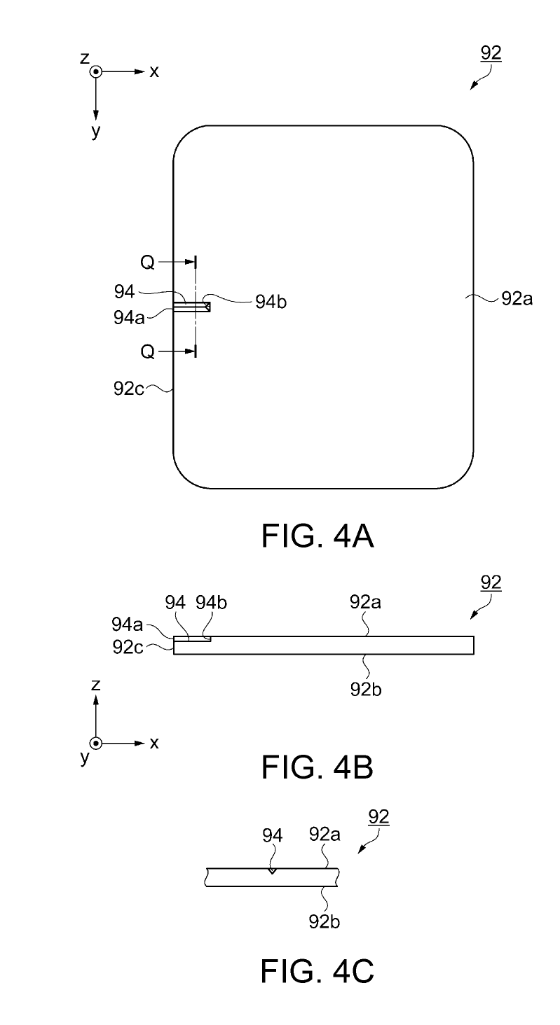

The package 9 has the internal space 14 inside thereof, and the gyro element 2 is accommodated and installed in the internal space 14 which is air-tight. In addition, after exhaust (deaeration) is performed, a communication portion that is a gap between a rear surface 92b on the opposite side to the surface 92a of the lid 92 on the side on which the groove 94 is provided and the seam ring 93 is closed by a sealing portion 95 solidified after being melted by an energy beam (for example, laser light), whereby the internal space 14 with the gyro element 2 accommodated therein is hermetically sealed. In addition, an end portion on the external side of the groove 94, that is, a portion which includes an outer peripheral surface 92c (refer to FIGS. 4A to 4C) of the lid 92 is melted and solidified, whereby the sealing portion 95 is formed.

As a constituent material of the base 91, although it is not particularly limited, various ceramics such as aluminum oxide can be used. Further, a constituent material of the lid 92, although not particularly limited, is acceptable if it is a member having a linear expansion coefficient approximate to that of the constituent material of the base 91. For example, in a case where the constituent material of the base 91 is ceramic as described above, an alloy such as Kovar is preferable.

The gyro element 2 is fixed onto the upper surface of the bottom plate 911 through electrically-conductive fixing members 8 such as solder, silver paste, or an electrically-conductive adhesive (an adhesive with electrically-conductive fillers such as metal particles dispersed in a resin material) at the first and second supporting portions 51 and 52. Since the first and second supporting portions 51 and 52 are located at both end portions in the y-axis direction of the gyro element 2, such portions are fixed to the bottom plate 911, whereby the vibration body 4 of the gyro element 2 is supported at both ends, and thus it is possible to stably fix the gyro element 2 with respect to the bottom plate 911. For this reason, unnecessary vibration (vibration other than detection vibration) of the gyro element 2 is suppressed, and thus the detection accuracy of the angular velocity ω by the gyro element 2 is improved.

Further, six electrically-conductive fixing members 8 are provided to correspond to (to be in contact with) two detection signal terminals 714, two detection ground terminals 724, a drive signal terminal 734, and a drive ground terminal 744, which are provided at the first and second supporting portions 51 and 52, and to be separated from each other. Further, six connection pads 10 corresponding to the two detection signal terminals 714, the two detection ground terminals 724, the drive signal terminal 734, and the drive ground terminal 744 are provided on the upper surface of the bottom plate 911, and each of the connection pads 10 and any terminal corresponding thereto are electrically connected through the electrically-conductive fixing member 8.

### Lid as Lid Body

Here, the details of the lid 92 as the lid body will be described using FIGS. 4A to 4C. FIGS. 4A to 4C show an example of the lid as the lid body according to the invention, wherein FIG. 4A is a plan view, FIG. 4B is a cross-sectional front view of a portion in which the groove 94 is provided, and FIG. 4C is a cross-sectional view taken along line Q-Q of FIG. 4A.

The lid 92 as the lid body closes the opening of the concave portion which is open at the upper surface of the package 9, and is joined to the seam ring 93 at the periphery of the opening of the concave portion by using, for example, a seam welding method or the like. Described in detail, the lid 92 is a plate-shaped member having the surface 92a and the rear surface 92b which are in the relationship of being the front and back to each other, and the outer peripheral surface 92c connecting the surface 92a and the rear surface 92b. Since the lid 92 of this example has a plate shape, the formation thereof is easy and furthermore, the stability of the shape is also excellent. In particular, the groove 94 (described later) is a very small groove. However, the formation thereof can also be easily performed. Further, a plate material such as Kovar is used for the lid 92 of this example. A Kovar plate is used for the lid 92, whereby at the time of sealing, the seam ring 93 formed of Kovar and the lid 92 are melted in the same molten state and also easily alloyed, and therefore, it is possible to easily and reliably perform sealing. In addition, other plate materials instead of Kovar may be used for the lid 92, and for example, a metal material such as a 42 alloy or stainless steel, or the same material as the side wall 912 of the package 9, or the like can be used.

Then, when the lid 92 is viewed in a plan view from the surface 92a side, the bottomed groove 94 toward the central portion of the lid 92 from one side portion of the outer peripheral surface 92c is provided on the surface 92a side. The groove 94 is provided such that the shape of an opening viewed from the outer peripheral surface 92c side is a wedge shape (for example, a triangle having two vertices on the surface 92a side), and is located at approximately the center of one side portion in a plan view. The groove 94 is provided toward the central portion from the outer peripheral surface 92c of the lid 92 on at least a position which overlaps the upper surface of the package 9 in a plan view, on the surface 92a on the opposite side to a placement surface on the package 9 (the rear surface 92b) when the lid 92 is placed so as to close the opening of the concave portion which is open at the upper surface of the package 9. In addition, in this example, the groove 94 is provided toward the central portion from the outer peripheral surface 92c of the lid 92 so as to have a portion which overlaps the opening of the concave portion which is open at the upper surface of the package 9 in a plan view. In other words, the groove 94 has an end on one side 94a which is open at the outer peripheral surface 92c, and an end on the other side 94b on the central portion side, and the end on the other side 94b on the central portion side is provided so as to reach further to the inside (the internal space that is the center side of the package in a plan view) than an inner wall of the frame-shaped side wall 912 provided at the peripheral portion of the upper surface of the bottom plate 911 configuring the base 91. That is, the end on the other side 94b of the groove 94 is provided at a position which overlaps further to the inside (the internal space that is the center side of the package in a plan view) than the inner wall of the side wall 912 in a plan view. By providing the groove 94 in this manner, it is possible to reliably provide a gap through which it is possible to perform exhaust from the internal space 14 of the package 9, as described later.

In addition, in this embodiment, an example has been described in which the groove 94 is located at approximately the center of one side portion which is a long side of the lid 92 in a plan view. However, the invention is not limited thereto, and the groove 94 may be provided at any place of at least one side portion of the lid 92. Further, the groove 94 may be provided at one side portion which is a short side in a plan view. By providing the groove 94 at a short side of the lid 92 in a plan view, it is possible to obtain the following effects. In the package 9, it is easy for deformation in the thickness direction (the z-axis direction) to become larger in along side direction than a short side direction. For this reason, in the lid 92 joined to the package 9, residual stress higher than that in the short side direction exists in the long side direction. If a portion in which the groove 94 is formed is melted for sealing (described later) with high residual stress retained, the residual stress is applied to a sealing portion, and thus there is a concern that the reliability in sealing may be damaged, and therefore, by providing the groove 94 at the short side in which residual stress is relatively low, it becomes possible to reduce the influence of residual stress on the sealing portion.

Further, the width of the groove 94 is not particularly limited. However, it is preferable that the width of the groove 94 is greater than or equal to 1 μm and less than or equal to 200 μm. In addition, it is further preferable that the width of the groove 94 is greater than or equal to 70 μm and less than or equal to 200 μm in order to secure both an exhaust characteristic (a formation characteristic of an unwelded portion) and a sealing characteristic. Further, the depth of the groove 94 is not particularly limited. However, it is preferable that the depth of the groove 94 is greater than or equal to 5 μm and less than or equal to 30 μm.

Further, there is a case in which seal welding is performed after a metal layer (not shown) capable of being melted by the seam welding is formed at each of the base 91 and the lid 92 in a joint portion between the base 91 and the lid 92. However, also in this case, the lid 92 described above can be applied.

Then, after exhaust of the concave portion (the internal space 14) is performed from a gap between the package 9 and the lid 92, which is an unwelded portion that can be formed by the groove 94, the lid 92 which is located above the unwelded portion (a portion in which the groove 94 is formed) and/or the seam ring 93 which is located below the unwelded portion is welded by an energy beam such as laser light. In this manner, the gap of the unwelded portion is closed by the sealing portion 95 as a melted portion which is formed by the melted lid 92 and/or the melted seam ring 93, and thus the internal space 14 is hermetically sealed.

In addition, in this embodiment, an example has been described in which a single groove 94 is provided in the lid 92. However, the number and the disposition of the grooves are not limited thereto, and a plurality of grooves may be provided and a configuration is also acceptable in which grooves are provided in both the surface 92a and the rear surface 92b of the lid 92.

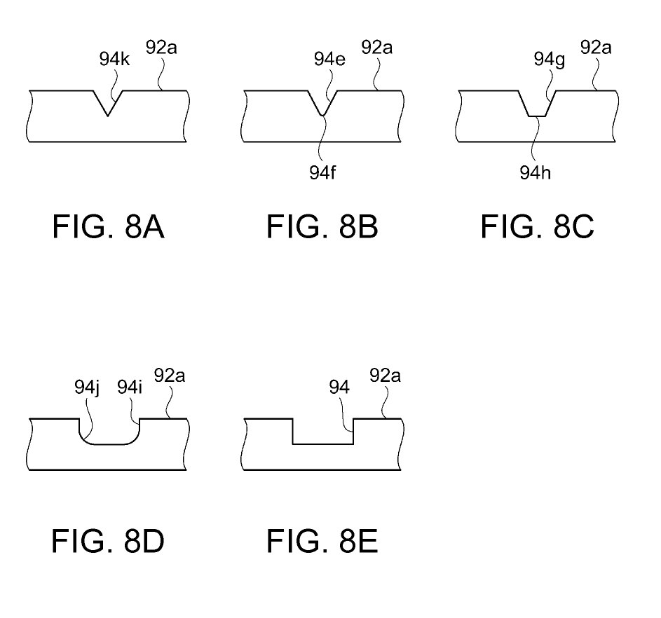

Further, as the transverse cross-sectional shape of the wall surface of the groove 94 shown in a cross-sectional view along line Q-Q of FIG. 4C, a triangular wedge shape having two vertices on the surface 92a side is used. However, a shape in which welding by seam welding is not performed, such as a rectangular shape, a curved shape, or a semicircular shape (an arc shape), is also acceptable, and the shape does not matter. In addition, the transverse cross-sectional shape of the wall surface of the groove 94 will be described in detail later (refers to FIGS. 8A to 8E).

### Method of Manufacturing Vibrator

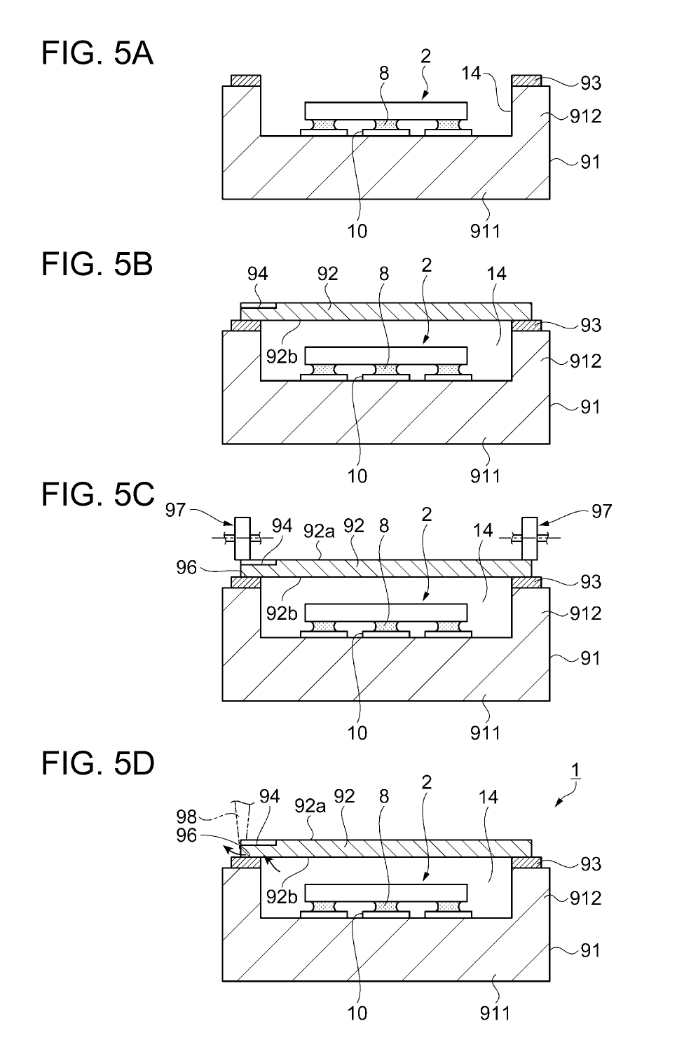

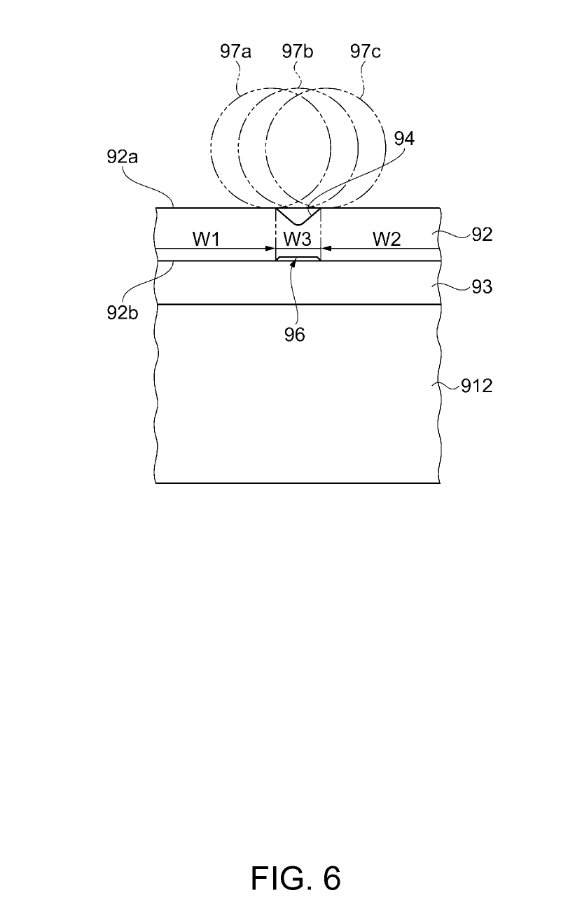

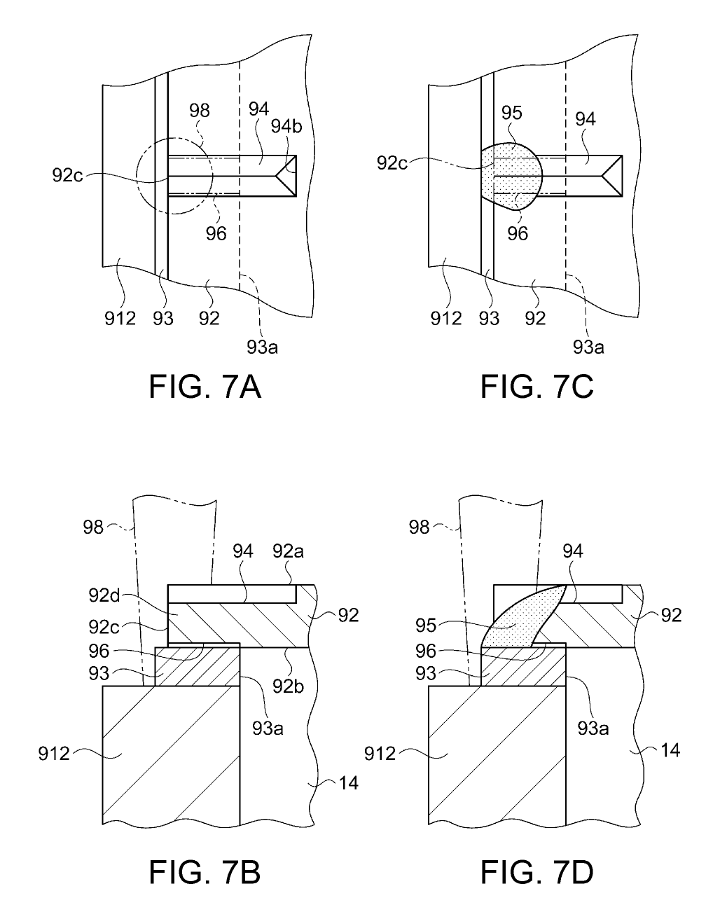

Next, a method of manufacturing the vibrator as the electronic device according to the invention will be described with reference to FIGS. 5A to 7D. FIGS. 5A to 5D are cross-sectional front views showing an outline of a process of manufacturing the vibrator as the electronic device shown in FIGS. 1, 2A, and 2B described above. FIG. 6 is a diagram showing a joint state of the lid and the base and is a cross-sectional view when the groove provided in the lid is viewed from the outer peripheral surface side of the lid. FIGS. 7A, 7B, 7C, and 7D are diagrams showing a sealing process, wherein FIG. 7A is a plan view showing the state before sealing, FIG. 7B is a front view of FIG. 7A, FIG. 7C is a plan view showing the state after sealing, and FIG. 7D is a cross-sectional front view of FIG. 7C.

First, a process of accommodating the gyro element 2 as the electronic component in the internal space 14 of the base 91 will be described. As shown in FIG. 5A, the base 91 is prepared which has the plate-shaped bottom plate 911 and the frame-shaped side wall 912 provided at the peripheral portion of the upper surface of the bottom plate 911 and also has a concave space which is surrounded by the bottom plate 911 and the inner wall of the side wall 912 and is open at the upper surface. In the base 91, the seam ring 93 is formed on the upper surface 912a of the frame-shaped side wall 912 and the connection pads 10 are formed on the upper surface of the bottom plate 911. Further, the gyro element 2 described above is prepared. Then, the gyro element 2 is fixed by making an electrical connection with the connection pads 10. For the connection, it is possible to use the electrically-conductive fixing member 8 such as solder, silver paste, or an electrically-conductive adhesive (an adhesive with electrically-conductive fillers such as metal particles dispersed in a resin material). At this time, the gyro element 2 has a void between itself and the upper surface of the bottom plate 911 due to the thickness of the electrically-conductive fixing member 8.

Next, a process of placing the lid 92 as the lid body above the concave space will be described. As shown in FIG. 5B, the lid 92 as the lid body described above is placed on the seam ring 93 in order to hermetically retain the gyro element 2 accommodated in the internal space 14. The groove 94 is provided in the surface 92a of the lid 92. The lid 92 is disposed such that the rear surface 92b is on the seam ring 93 side, as shown in FIG. 6, and in a plan view (in the case of being viewed from the lid 92 side), the end on one side 94a on the outer periphery side of the groove 94 is located above the seam ring 93 and the end on the other side 94b on the internal space 14 side of the groove 94 is located at a position overlapping the internal space 14.

Next, a joining process (a first welding process) of joining the lid 92 to the base 91 by the seam ring 93 will be described. As shown in FIG. 5C, the lid 92 and the seam ring 93 are joined to each other by performing seam welding on a portion where the lid 92 and the seam ring 93 confront each other on the frame-shaped side wall 912, in a rectangular circumference shape by using a roller electrode 97 of a seam welder. That is, the lid 92 is joined to the base 91. The roller electrode 97 is brought into pressure contact with the lid 92 from the opposite side to the base 91 by a pressing mechanism (not shown). Then, the roller electrode 97 travels at a predetermined speed along an outer peripheral side of the lid 92 in a plan view while rotating around an axis. At this time, the seam ring 93 or joining metal is melted due to Joule heat by making an electric current flow between the roller electrodes 97 through the lid 92 and the seam ring 93, and thus the lid 92 and the seam ring 93 are joined to each other. In this manner, the lid 92 is welded (joined) to the base 91 through the seam ring 93 provided on the upper surface 912a of the frame-shaped side wall 912 configuring the base 91. Here, at a site where the groove 94 is provided, an unwelded portion 96 in which the above-described welding is not performed and thus the lid 92 and the seam ring 93 are not welded to each other is formed. However, the details thereof will be described later. In addition, it is also possible to use a configuration or a method in which the lid 92 is directly welded (joined) to the base 91.

Here, joining of the site where the groove 94 is provided will be described using FIG. 6. As shown in FIG. 6, the roller electrode 97 moves toward the right from the left in the drawing. At a position 97a, the roller electrode 97 is in pressure contact with the lid 92, and therefore, the seam ring 93 or the joining metal is melted due to Joule heat, as described above, and thus the lid 92 and the seam ring 93 are joined to each other. At a position 97b to which the roller electrode 97 has further moved, the roller electrode 97 does not come into contact with the lid 92 due to the groove 94, or contact becomes incomplete, and thus sufficient Joule heat for welding is not generated, whereby welding cannot be performed. At a position 97c to which the roller electrode 97 has further moved, similar to the position 97a, the roller electrode 97 is in pressure contact with the lid 92, and therefore, the seam ring 93 or the joining metal is melted due to Joule heat, as described above, and thus the lid 92 and the seam ring 93 are joined to each other. That is, seam welding is performed at portions indicated by W1 and W3 in the drawing, and seam welding is not performed at a portion indicated by W2. In this manner, the unwelded portion 96 in which seal welding is not performed is formed between the lid 92 in the portion in which the groove 94 is provided and the seam ring 93. The unwelded portion 96 becomes a local gap extending from the outer peripheral surface 92c of the lid 92 to an inner peripheral surface 93a of the seam ring 93, that is, making the internal space 14 communicate with the outside of the base 91, as shown in FIGS. 7A to 7D, and functions as an exhaust hole in a subsequent process of performing exhaust. In addition, in FIGS. 6, and 7A to 7D, in order to clearly describe the unwelded portion 96, the unwelded portion 96 is described as being formed in a concave shape in the lid 92. However, the lid 92 does not actually become concave.

Next, a process of performing exhaust from the internal space 14 by using the groove 94 (the exhaust hole) will be described with reference to FIG. 5D. In this embodiment, a gap which is the unwelded portion 96 (not shown in FIG. 5D) which is not welded at the time of the above-described seam welding is provided to extend as a communication portion reaching the internal space 14. Therefore, it is possible to exhaust gas in the internal space 14, as indicated by an arrow in the same drawing, by using the gap that is the unwelded portion 96 as the exhaust hole. Then, the shift to a sealing process of closing the unwelded portion 96 by melting the lid 92 by irradiating the lid 92 with laser light 98, and thereby hermetically sealing the internal space 14 after the exhaust is completed, is done. The sealing process will be described later. In addition, in this embodiment, an example has been described in which sealing is performed in a state where gas in the internal space 14 has been exhausted under reduced pressure. However, it is not limited to being done in the state under reduced pressure, and it is also possible to perform sealing under an inert gas atmosphere where inert gas or the like is introduced after the exhaust is done.

Next, the process of hermetically sealing the internal space 14 after the exhaust is completed will be described using FIGS. 7A to 7D. In the sealing process, in a state in which the exhaust of the internal space 14 has been completed, an energy beam (for example, laser light or an electron beam) is irradiated to the lid 92 in the portion (the communication portion) corresponding to the gap of the unwelded portion 96 used as the exhaust hole. In this embodiment, metal (Kovar) of the remaining portion is melted by irradiating the lid 92 with the laser light 98 as the energy beam. At this time, the laser light 98 is irradiated so as to be disposed such that an end portion on the external side of the unwelded portion 96 (the gap), that is, the end on one side of the unwelded portion 96 (the gap) which includes the outer peripheral surface 92c of the lid 92 is included in a spot of the laser light 98. Then, an upper portion 92d of the unwelded portion 96 (the gap) of the lid 92 in the portion in which the unwelded portion 96 is provided is melted with thermal energy by the irradiation of the laser light 98, and the molten metal flows onto the seam ring 93 while filling the gap of the unwelded portion 96. If the irradiation of the laser light 98 is stopped when the molten metal has sufficiently flowed, the metal which has been melted is solidified, and the solidified molten metal becomes the sealing portion (the melted portion) 95, thereby closing the gap of the unwelded portion 96. In this way, the internal space 14 is hermetically sealed.

As described above, the laser light 98 is irradiated such that the end portion on the external side of the unwelded portion 96 (the gap), that is, the end portion of the unwelded portion 96 (the gap) which includes the outer peripheral surface 92c of the lid 92 is included in the spot of the laser light 98, and thus the upper portion 92d of the lid which includes the end portion of the unwelded portion 96 (the gap) is melted, whereby the fluidity of the molten metal becomes good. In this manner, the fluidity of the molten metal is improved, whereby it is possible to reliably perform the sealing of the gap of the unwelded portion 96.

By using the method of manufacturing the vibrator 1 as the electronic device having such a process, the gap of the unwelded portion 96 serves as the exhaust hole as it is, and therefore, it is not necessary to perform dimensional control or the like on a unwelded portion (an exhaust hole) which is used for exhaust, as in the related art, and exhaust and joining (sealing) are stably performed, and therefore, even in a case where the vibrator 1 is heated to a high temperature after the joining (the sealing), it is possible to suppress the generation of gas. Further, due to stable exhaust and joining (sealing), it is possible to prevent the characteristic degradation of the gyro element 2 as the electronic component accommodated in the package 9 due to the influence of residual gas or the like, and thus it is possible to provide the vibrator 1 as the electronic device having stable characteristics.

In addition, in the description described above, an example has been described in which a single exhaust hole (the gap of the unwelded portion 96) is used. However, a plurality of exhaust holes may be provided. That is, the groove 94 may be provided as a plurality thereof. In this manner, in a case of using a plurality of exhaust holes, exhaust speed increases. However, a plurality of sealing places are also necessary.

### Modified Examples of Joining Process and Joint Structure

In the first embodiment described above, the joining method has been described in which the seam ring 93 which is a ring-shaped metal frame body is used as a joining material joining the base 91 and the lid 92 in which seam welding is performed by using the roller electrode 97 of the seam welder. However, it is possible to apply another joining method. That is, as another joining method, a joining method (a so-called direct seam method) can be applied in which as a joining material, a brazing material such as a silver brazing material is disposed on the upper surface 912a of the frame-shaped side wall 912 of the base 91 or the outer surface of the lid 92, the brazing material is melted by the roller electrode 97 of the seam welder, and the lid 92 and the base 91 are joined to each other by the molten metal brazing material. As still another joining method, a joining method can be applied in which instead of joining the lid 92 and the base 91 through the joining material, a portion of the lid is melted and the lid 92 and the base 91 are directly joined to each other by a member of the melted lid. According to these joining methods, the seam ring 93 is not required, and therefore, a reduction in size and a reduction in cost of the electronic device can be realized.

### Modified Example of Disposition of Groove in Joining Process

In addition, in the first embodiment described above, as shown in FIG. 7A, when the lid 92 has been placed on the seam ring 93 and joined to the base 91, the groove 94 extends from the outer peripheral surface 92c of the lid 92 to the internal space 14 in a plan view, whereby the communication portion which makes the internal space 14 and the outside of the base 91 communicate with each other is formed by the groove 94. However, the groove 94 may not extend to the internal space 14. That is, the groove 94 may not overlap the internal space 14 in a plan view and may exist in an area between the inner peripheral surface 93a of the seam ring 93 and the outer peripheral surface 92c of the lid 92. In this case, it is acceptable if the groove 94 is disposed on a rolling locus of the roller electrode 97 (refer to FIG. 6) of the seam welder, and a gap which is the unwelded portion 96 is formed between the lid 92 and the seam ring 93.

### Modified Examples of Groove

Here, an opening shape of the groove 94 provided in the lid 92 will be described using FIGS. 8A to 8E. FIGS. 8A to 8E show examples of the opening shape of the groove and are front views when the shape of the opening of the groove is viewed from the outer peripheral surface 92c side of the lid 92. In the embodiment described above, the opening shape (the cross-sectional shape) of the groove 94 provided in the lid 92 has been described by using the rectangular groove 94 as shown in FIG. 8E, as an example. However, the opening shape of the groove 94 is not limited thereto, and the shapes as shown in FIGS. 8A to 8D are also acceptable. It is preferable that the groove 94 has a shape in which an opening shape (a cross-sectional shape) when viewed from the outer peripheral surface 92c side of the lid 92 is made such that the area of a bottom surface is smaller than an opening area in the surface 92a of the lid 92, as shown in FIGS. 8A to 8D.

A groove 94k shown in FIG. 8A has a wedge shape (a triangle having two vertices on the surface 92a side). By adopting the groove 94k having such a wedge shape, it is possible to improve formability in a forming tool (for example, a molding die) when forming the groove 94k. That is, by making the tip of the forming tool have a tapered shape, it becomes possible to easily perform the pressing of the forming tool.

A groove 94e shown in FIG. 8B has a shape in which a tip portion 94f of a wedge shape has a curved rounded shape (an R shape). In this manner, by making the tip portion 94f have a rounded shape, in addition to the above-described good formability, it becomes possible to increase the strength of the tip of a forming tool, and thus it is possible to increase the lifetime of the forming tool and it is possible to continue to stably maintain the formability thereof.

A groove 94g shown in FIG. 8C has a trapezoidal shape in which a tip portion 94h of a wedge shape is formed with a narrow straight line portion. Also in the groove 94g in which the tip portion 94h is formed with a narrow straight line portion, similar to the groove 94e described above, in addition to good formability, it becomes possible to increase the strength of the tip of a forming tool, and thus it is possible to increase the lifetime of the forming tool and it is possible to continue to stably maintain the formability thereof.

A groove 94i shown in FIG. 8D has a shape in which a portion where the bottom surface and the side surface of a rectangular shape meet has a curved rounded shape (an R shape) 94j. According to the groove 94i, compared to the groove 94 shown in FIG. 8E, it becomes possible to increase the lifetime of a forming tool and improve formability thereof.

### Another Disposition Example of Groove

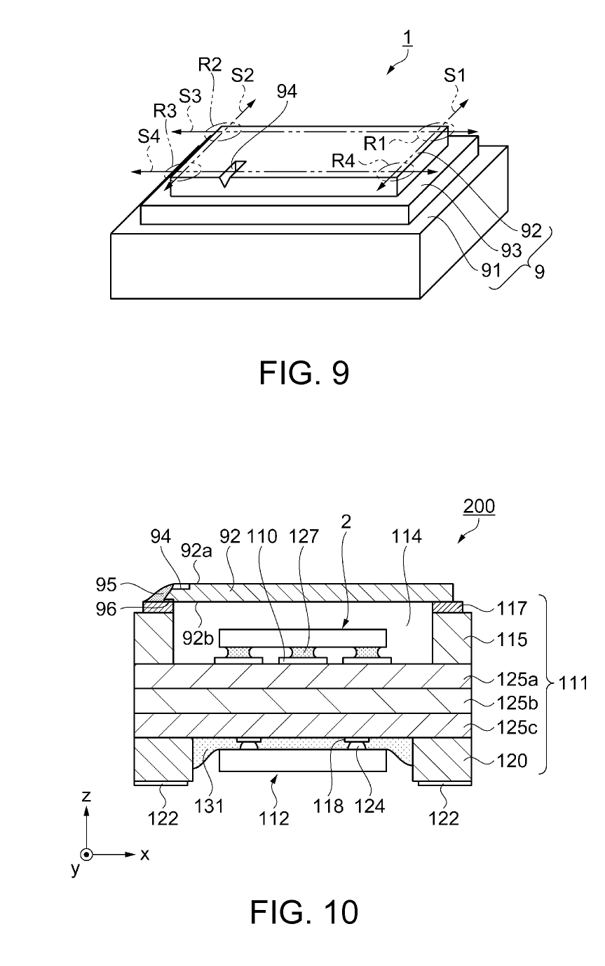

Here, another disposition example of the groove will be described with reference to FIG. 9. FIG. 9 is a perspective view for describing another disposition example of the groove. As shown in FIG. 9, the groove 94 according to this disposition example is provided in the vicinity of an end on one side of one side in the base 91 and the lid 92 configuring the package 9. The details will be described below.

When the base 91 is joined to the lid 92 through the seam ring 93 by seam welding, a seam welding roller moves along the edge of each side, as shown by loci S1, S2, S3, and S4. The seam welding roller moves in this manner. For this reason, at each of the four corner portions, the seam welding roller passes twice. Therefore, if the groove 94 is provided in any of areas R1, R2, R3, and R4 in which the seam welding roller passes through twice, seam welding is performed twice, and thus the groove 94 is easily closed.

Further, in the vicinity of the central portion of each side in the base 91 and the lid 92, it is easy for deformation in the thickness direction to become larger than in the vicinity of an end portion. For this reason, in the vicinity of the central portion of each side of the lid 92 joined to the package 9, higher residual stress than in the vicinity of the end portion exists. If the groove 94 is sealed by melting with the high residual stress retained, the residual stress is applied to the sealing portion, and thus there is a concern that the reliability in sealing may be damaged. In order to avoid this, by providing the groove 94 in the vicinity of the end portion of each side in which residual stress is relatively low, in other words, by providing the unwelded portion 96 (refer to FIG. 6) and the sealing portion 95 (refer to FIGS. 7A to 7D) as the melted portion, it becomes possible to reduce the influence of the residual stress on the sealing portion.

In this manner, by providing the groove 94 in the vicinity of the end on one side of one side of the lid 92 avoiding the areas R1, R2, R3, and R4 in which the seam welding roller passes through twice, it becomes possible to perform the formation of the unwelded portion 96 more stably (refer to FIG. 6) and the sealing with improved reliability. In addition, in this example, an example in which the groove 94 is provided in the long side has been described. However, the same applies to a configuration in which the groove 94 is provided in the short side.

According to the vibrator 1 of the first embodiment described above, the unwelded portion 96 in which the seam welding of the lid 92 and the seam ring 93 is not performed is formed by the groove 94 provided in the lid 92. The unwelded portion 96 becomes a local gap extending from the outer peripheral surface 92c of the lid 92 to the inner peripheral surface 93a of the seam ring 93, that is, making the internal space 14 and the outside of the base 91 communicate with each other, and functions as the exhaust hole during the process of performing exhaust. Then, by using the unwelded portion 96 as the exhaust hole, it is possible to easily make the internal space 14 have reduced pressure or an inert gas atmosphere. Then, by closing the gap (the unwelded portion 96) by irradiating the lid 92 in the unwelded portion 96 with the laser light 98, it is possible to easily seal the internal space 14 having reduced pressure or an inert gas atmosphere. In this way, sealing after gas generated during the joining of the lid 92 is removed from the inside of the package 9 becomes possible, and thus it is possible to provide the vibrator 1 in which high-quality airtight sealing is realized.

### Second Embodiment of Electronic Device

Next, an embodiment of a gyro sensor as a second embodiment of the electronic device will be described using FIG. 10. FIG. 10 is a cross-sectional front view showing an outline of the gyro sensor. In addition, in this embodiment, the same configuration as in the first embodiment described above is denoted by the same reference numeral and description thereof is sometimes omitted.

A gyro sensor 200 is provided with the gyro element 2 as an electronic component, an IC 112 as a circuit element, a package (a base) 111 as a container, and the lid 92 as a lid body. The package 111 formed of ceramics or the like has a third substrate 125c, a second substrate 125b, and a first substrate 125a which are laminated, a frame-shaped side wall 115 provided at a peripheral portion of the surface of the first substrate 125a, and a frame-shaped side wall 120 provided at a peripheral portion of the surface of the third substrate 125c.

A seam ring 117 as a joining material formed of an alloy such as Kovar, is formed on the upper surface of the frame-shaped side wall 115. The seam ring 117 has a function as a joining material of the lid 92 and is provided in a frame shape (a circumference shape) along the upper surface of the side wall 115. In the lid 92, the groove 94 is provided at an end portion of the rear surface 92b which is a surface facing the seam ring 117. In addition, the configuration of the lid 92 is the same as that in the first embodiment described above. The groove 94 is formed so as to communicate with an internal space 114 when the lid 92 is placed on the seam ring 117. Here, a space surrounded by the surface (a lower surface in the drawing) of the first substrate 125a and the inner wall of the frame-shaped side wall 115 becomes the internal space 114 in which the gyro element 2 is accommodated, and a space surrounded by the third substrate 125c and the inner wall of the frame-shaped side wall 120 becomes an accommodation portion for the IC 112. In addition, the internal space 114 with the gyro element 2 accommodated therein is sealed by the sealing portion 95 formed by being solidified after the lid 92 which remains at the portion in which the groove 94 is formed is melted, after exhaust (deaeration) is performed through the groove 94. Further, a plurality of external terminals 122 are provided on the surface (a lower surface in the drawing) of the frame-shaped side wall 120.

A plurality of connection pads 110 are formed on the surface of the first substrate 125a which is located in the internal space 114 for the gyro element 2, and the gyro element 2 is fixed by making an electrical connection with the connection pads 110. For the connection, an electrically-conductive fixing member 127 such as solder, silver paste, or an electrically-conductive adhesive (an adhesive with electrically-conductive fillers such as metal particles dispersed in a resin material) can be used. At this time, the gyro element 2 has a void between itself and the surface of the first substrate 125a due to the thickness of the electrically-conductive fixing member 127.

The internal space 114 with the gyro element 2 accommodated therein is closed with the lid 92 as the lid body at an opening thereof, thereby being hermetically sealed. The lid 92 has the same configuration as the lid 92 described in the first embodiment described above, and therefore, the detailed description thereof is omitted, and an outline will be described. The lid 92 closes an opening of the internal space 114 which is open at the upper surface of the package 111, and is joined at the periphery of the opening by using, for example, a seam welding method or the like. A Kovar plate material is used for the lid 92, and the lid 92 has the surface 92a and the rear surface 92b which are in the relationship of being the front and back to each other. Similar to the first embodiment described above, in the lid 92, the bottomed groove 94 provided toward the internal space 114 (a central portion) from the outer peripheral surface of the lid 92 is provided on the rear surface 92b side. Then, after exhaust of the internal space 114 is performed through the groove 94 which is a gap between the seam ring 117 and the lid 92, airtight sealing of the internal space 114 is performed by melting the portion which includes an end portion of the groove 94 by laser light or the like and solidifying the portion.

On the other hand, a connection electrode 118 is formed on the surface of the third substrate 125c which is located at the accommodation portion for the IC 112, and the connection electrode 118 and the IC 112 are fixed to each other by making an electrical connection with a gold (Au) bump 124 or the like. A gap between the IC 112 and the surface of the third substrate 125c is filled with an underfill material 131 such as resin. The resin may be provided so as to cover the IC 112. In addition, each of the connection pad 110, the connection electrode 118, the external terminal 122, and the like is connected with internal wiring or the like. However, description and illustration in this embodiment are omitted.

### Method of Manufacturing Gyro Sensor

Next, a method of manufacturing the gyro sensor 200 will be described. However, description of the same processes as the processes described in the method of manufacturing the vibrator 1 described above is omitted. The processes which are omitted are a process of accommodating the gyro element 2 in the internal space 114 of the package 111 as a base, a process of placing the lid 92 so as to cover the internal space 114, a joining process of joining the lid 92 to the package 111, and a sealing process of hermetically sealing the internal space 114 after exhaust is completed.

In addition to the above-described processes, during the manufacturing of the gyro sensor 200, the IC 112 is accommodated in the accommodation portion for the IC 112 surrounded by the frame-shaped side wall 120 provided at the peripheral portion of the surface of the third substrate 125c. The IC 112 is fixed to the connection electrode 118 provided on the surface of the third substrate 125c, by making an electrical connection using the gold (Au) bump 124. The underfill material 131 such as resin is filled in a gap between the IC 112 and the surface of the third substrate 125c. The gyro sensor 200 is completed through the above-described processes.

According to the second embodiment described above, similar to the first embodiment, the fluidity of the molten metal (the lid 92) by laser light becomes good, and thus it becomes possible to reliably perform the formation of the sealing portion 95. Therefore, it is possible to reliably perform the sealing of the groove 94, and thus the manufacture of the gyro sensor 200 as the electronic device with improved reliability in airtightness becomes possible. Further, since the groove 94 serves as the exhaust hole, it is not necessary to perform dimensional control or the like for a unwelded portion (an exhaust hole) which is used for exhaust, as in the related art, and exhaust and joining (sealing) are stably performed, and therefore, even in the case that the gyro sensor 200 is heated to a high temperature after the joining (the sealing), it is possible to suppress generation of gas. Further, due to stable exhaust and joining (sealing), it is possible to prevent the characteristic degradation of the gyro element 2 as the electronic component accommodated in the package 111 due to the influence of residual gas or the like, and thus it is possible to provide the gyro sensor 200 as an electronic device having stable characteristics.

In the description of the electronic device described above, the vibrator 1 and the gyro sensor 200 each using the gyro element 2 of a so-called double T type as the electronic component have been described as an example. However, the invention is not limited thereto, and it is possible to apply the invention to an electronic device in which an element is air-tightly accommodated in a package. As other electronic devices, for example, a gyro sensor using as an H type or tuning fork type gyro element as an electronic component, a timing device (a vibrator, an oscillator, or the like) using a vibration element, a pressure sensor using a pressure-sensitive element, a semiconductor device using a semiconductor element, and the like are also acceptable.

In addition, as the vibration element, it is possible to suitably use a piezoelectric vibration element such as a MEMS element using a piezoelectric body, a quartz crystal vibrator element performing flexural vibration, such as a tuning fork type quartz crystal vibrator element using quartz crystal for a material thereof, a longitudinal vibration type quartz crystal vibrator element, a thickness-shear quartz crystal vibrator element, or the like.

### Electronic Apparatus

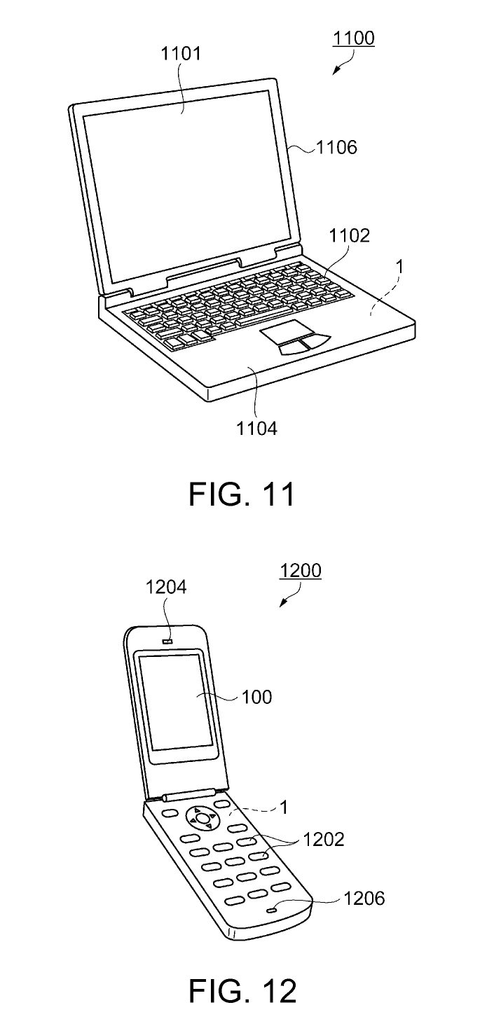

Subsequently, an electronic apparatus to which the vibrator 1 as the electronic device according to an embodiment of the invention or the gyro sensor 200 as the electronic device is applied will be described in detail based on FIGS. 11 to 13. In addition, in the description, an example is shown in which the vibrator 1 uses the gyro element 2.

FIG. 11 is a perspective view showing an outline of the configuration of a mobile type (or a notebook type) personal computer as the electronic apparatus which is provided with the vibrator 1 as the electronic device according to an embodiment of the invention. In this drawing, a personal computer 1100 is configured to include a main body section 1104 provided with a keyboard 1102, and a display unit 1106 provided with a display section 1101, and the display unit 1106 is supported so as to be able to rotate with respect to the main body section 1104 through a hinge structure section. In the personal computer 1100, the vibrator 1 using the gyro element 2 having a function of detecting angular velocity is built therein.

FIG. 12 is a perspective view showing an outline of the configuration of a mobile phone (also includes a PHS) as the electronic apparatus which is provided with the vibrator 1 as the electronic device according to an embodiment of the invention. In this drawing, a mobile phone 1200 is provided with a plurality of operation buttons 1202, an ear piece 1204, and a mouthpiece 1206, and a display section 100 is disposed between the operation buttons 1202 and the ear piece 1204. In the mobile phone 1200, the vibrator 1 using the gyro element 2 functioning as an angular velocity sensor or the like is built therein.

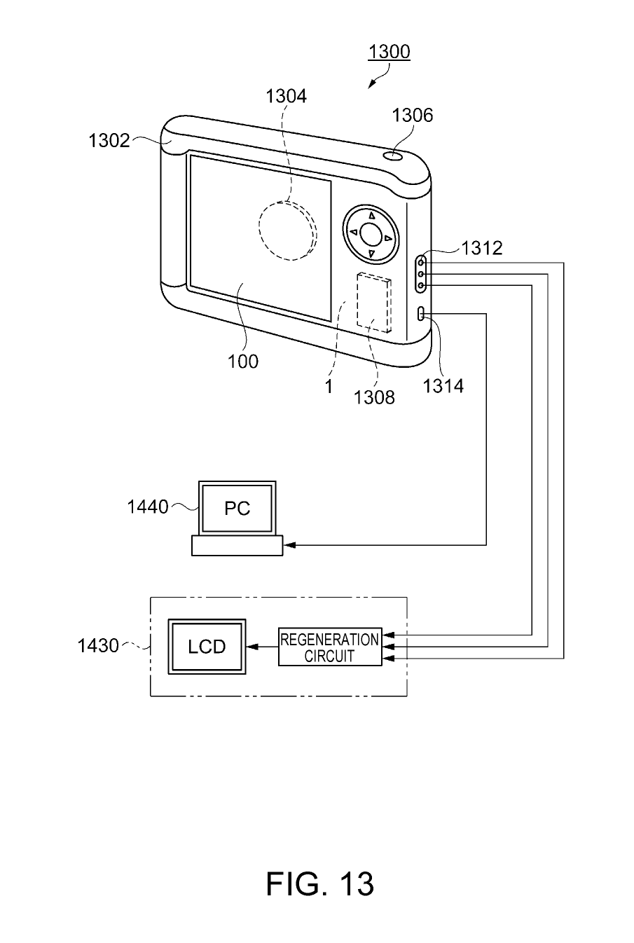

FIG. 13 is a perspective view showing an outline of the configuration of a digital still camera as the electronic apparatus which is provided with the vibrator 1 as the electronic device according to an embodiment of the invention. In addition, in this drawing, connection with external equipment is also shown in a simplified manner. Here, an ordinary camera exposes a silver halide photographic film to light through an optical image of a photographic subject, whereas a digital still camera 1300 produces an imaging single (an image signal) by performing photoelectric conversion of an optical image of a photographic subject through an imaging element such as a charged coupled device (CCD).

A configuration is made in which a display section 100 is provided on the back surface of a case (a body) 1302 in the digital still camera 1300 and display is performed based on the imaging signal by the CCD, and the display section 100 functions as a finder which displays a photographic subject as an electronic image. Further, a light receiving unit 1304 which includes an optical lens (an imaging optical system), the CCD, or the like is provided on the front side (the back side in the drawing) of the case 1302.

If a photographer confirms a photographic subject image displayed on the display section 100 and presses a shutter button 1306, the imaging signal of the CCD at that point in time is transmitted to and stored in a memory 1308. Further, in the digital still camera 1300, a video signal output terminal 1312 and an input-output terminal for data communication 1314 are provided on the side surface of the case 1302. Then, as shown in the drawing, as necessary, a television monitor 1430 is connected to the video signal output terminal 1312 and a personal computer 1440 is connected to the input-output terminal for data communication 1314. In addition, a configuration is made in which the imaging signal stored in the memory 1308 is output to the television monitor 1430 or the personal computer 1440 by a predetermined operation. In the digital still camera 1300, the vibrator 1 using the gyro element 2 functioning as an angular velocity sensor or the like is built therein.

In addition, the vibrator 1 according to an embodiment of the invention can be applied to, in addition to the personal computer (the mobile type personal computer) in FIG. 11, the mobile phone in FIG. 12, and the digital still camera in FIG. 13, an electronic apparatus such as an ink jet type discharge apparatus (for example, an ink jet printer), a laptop type personal computer, a television, a video camera, a video tape recorder, a car navigation device, a pager, an electronic notebook (also including an electronic notebook with a communication function), an electronic dictionary, a desktop electronic calculator, electronic game equipment, a word processor, a workstation, a video phone, a security television monitor, electronic binoculars, a POS terminal, medical equipment (for example, an electronic thermometer, a sphygmomanometer, a blood glucose meter, an electrocardiogram measuring device, an ultrasonic diagnostic device, or an electronic endoscope), a fish finder, various measuring instruments, meters and gauges (for example, meters and gauges of a vehicle, an aircraft, or a ship), or a flight simulator, for example.

### Moving Object

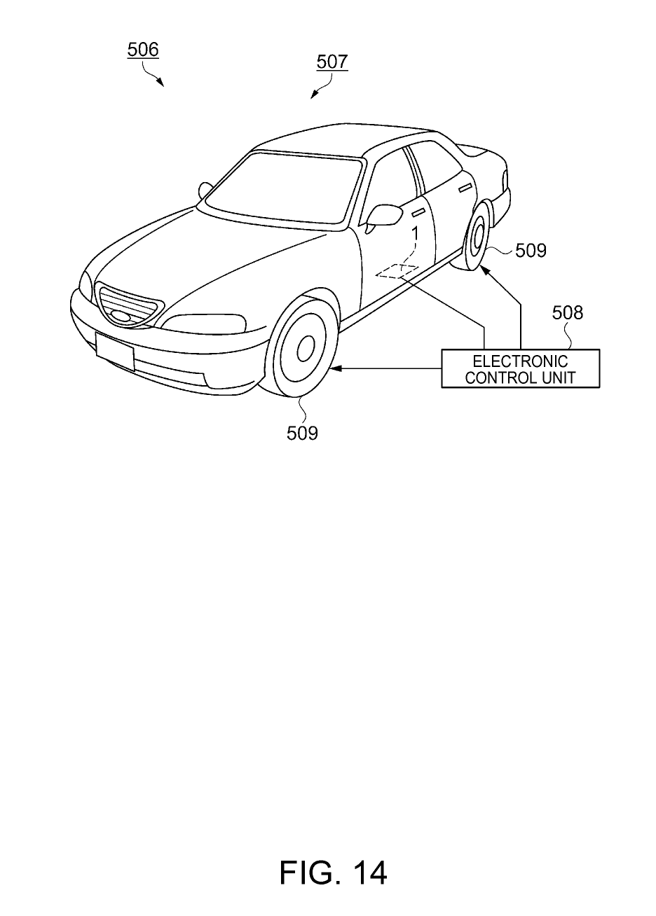

FIG. 14 is a perspective view schematically showing an automobile as an example of a moving object. In an automobile 506, the vibrator 1 as the electronic device according to the invention is mounted. For example, as shown in the same drawing, in the automobile 506 as the moving object, an electronic control unit 508 having the vibrator 1 using the gyro element 2 built-in and controlling tires 509 or the like is mounted on a car body 507. In addition, the vibrator 1 can also be widely applied to an electronic control unit (ECU) of a keyless entry, an immobilizer, a car navigation system, a car air conditioner, an antilock brake system (ABS), an airbag, a tire pressure monitoring system (TPMS), an engine control, a battery monitor of a hybrid car or an electric car, a car body attitude control system, or the like.

The entire disclosure of Japanese Patent Application No. 2013-226522, filed Oct. 31, 2013 is expressly incorporated by reference herein.

What is claimed is:

1. A method of manufacturing an electronic device in which an electronic component is accommodated in an internal space provided by a base and a lid body, comprising:
preparing the lid body in which a groove is provided in a surface on the opposite side to a surface on a side which is joined to the base;
seam-welding the base and the lid body at a site except for an unwelded site which includes a site corresponding to at least a portion of the groove, of a site planned to join the base and the lid body; and
welding the base and the lid body at the unwelded site.

2. The method of manufacturing an electronic device according to claim 1, wherein the groove reaches a position which overlaps the internal space, from an end portion of an outer periphery of the lid body in a plan view.

3. The method of manufacturing an electronic device according to claim 1, further comprising: performing exhaust of the internal space through the unwelded site between the seam-welding and the welding.

4. The method of manufacturing an electronic device according to claim 1, wherein a cross-sectional shape of the groove when viewed from an end portion side of the outer periphery is made such that an area of a bottom surface is smaller than an opening area.

5. An electronic device manufactured using the method of manufacturing an electronic device according to claim 1.

6. An electronic device manufactured using the method of manufacturing an electronic device according to claim 2.

7. An electronic device manufactured using the method of manufacturing an electronic device according to claim 3.

8. An electronic device manufactured using the method of manufacturing an electronic device according to claim 4.

9. An electronic apparatus comprising: the electronic device manufactured using the method of manufacturing an electronic device according to claim 1.

10. An electronic apparatus comprising: the electronic device manufactured using the method of manufacturing an electronic device according to claim 2.

11. An electronic apparatus comprising: the electronic device manufactured using the method of manufacturing an electronic device according to claim 3.

12. An electronic apparatus comprising: the electronic device manufactured using the method of manufacturing an electronic device according to claim 4.

13. A moving object comprising: the electronic device manufactured using the method of manufacturing an electronic device according to claim 1.

14. A moving object comprising: the electronic device manufactured using the method of manufacturing an electronic device according to claim 2.

15. A moving object comprising: the electronic device manufactured using the method of manufacturing an electronic device according to claim 3.

16. A moving object comprising: the electronic device manufactured using the method of manufacturing an electronic device according to claim 4.

17. A lid body which is welded to a base so as to form an internal space, comprising:
a groove provided in a surface on the opposite side to a surface on a side which is joined to the base,
wherein the lid body is seam-welded to the base at a site except for an unwelded site which includes a site corresponding to at least a portion of the groove, of a site planned to be welded to the base.
